(19) United States
(12) Patent Application Publication
(10) Pub. No.: US 2014/0308807 A1
(43) Pub. Date: Oct. 16, 2014

(54) METHOD FOR FABRICATING A SEMICONDUCTOR MEMORY

(71) Applicant: INOTERA MEMORIES, INC., Taoyuan (TW)

(72) Inventors: Yaw-Wen Hu, Taoyuan County (TW); Ron Fu Chu, Taipei City (TW); Tzung-Han Lee, Taipei City (TW)

(73) Assignee: INOTERA MEMORIES, INC., Taoyuan (TW)

(21) Appl. No.: 14/249,357

(22) Filed: Apr. 10, 2014

(30) Foreign Application Priority Data
Apr. 10, 2013 (TW) 102112769

(51) Int. Cl. H01L 21/28

(52) U.S. Cl. CPC H01L 21/28008
USPC 438/589

(57) ABSTRACT

A method for fabricating a semiconductor memory includes the following steps. Active areas are defined in a substrate. An oxide layer is then formed on the active areas. The oxide layer is subjected to a surface treatment. A first polysilicon layer, a buffer layer and a hard mask are deposited. Recessed access devices are formed in an array region of the substrate. After the recessed access devices are formed, the hard mask and the buffer layer are removed to thereby form transistors in a peripheral region. A second polysilicon layer is deposited on the first polysilicon layer. The first and second polysilicon layers are then etched into a gate structure.

### BACKGROUND OF THE INVENTION

1. Field of the Invention

The present invention relates to a method for fabricating a semiconductor, and more particularly to an improved method for fabricating a semiconductor memory.

2. Description of the Prior Art

It is known that gate oxide breakdown or rupture of a transistor in peripheral circuit regions of a memory reduces the yield of the fabrication of semiconductors, and causes reliability issues of the memory device. It is proposed that such defects mainly result from re-growing of polysilicon due to stresses generated during fabrication.

Thus, an improved method for fabricating a semiconductor memory is provided, which can effectively avoid the gate oxide breakdown or rupture in peripheral circuit regions during a memory fabrication process.

### SUMMARY OF THE INVENTION

To fulfill said objective, the present invention provides a method for fabricating a semiconductor memory comprising: providing a semiconductor substrate having a memory array region and a peripheral circuit region thereon; forming active areas in the semiconductor substrate; forming an oxide layer on the active areas, wherein the oxide layer acts as a gate oxide layer in the peripheral circuit region; subjecting the oxide layer to a surface treatment; depositing a first polysilicon layer, a buffer layer, and a hard mask on the oxide layer; fabricating recessed access devices in the memory array region, which comprises forming an opening in the hard mask within the memory array region by using lithographic and etching processes, and performing a dry etching process to etch the buffer layer, the first polysilicon layer, the oxide layer, and the semiconductor substrate through the opening to thereby forma trench; forming a gate oxide layer on a surface of the trench; depositing metal into the trench and filling the trench with a dielectric layer; removing the hard mask and the buffer layer; fabricating transistors in the peripheral circuit region, which comprises depositing a second polysilicon layer on the first polysilicon layer; and patterning the first and second polysilicon layers into a gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 6 are cross-sectional view diagrams illustrating the method for fabricating a semiconductor memory in accordance with an exemplary embodiment of the present invention.

### DETAILED DESCRIPTION

In the following, the present invention will be detailed with reference to all figures. The figures, which comprise a part of the present invention, are drawn to provide ease of explanation and for illustrating a preferable embodiment of the present invention. The embodiment below has been disclosed and explained so that a person who has ordinary skill in the art can understand and utilize the following teachings after reading the following. Modifications of the method of the present invention are also possible, and the method detailed therein may also be performed to form an alternative structure based on the present embodiment. Therefore, the following detailed description is not to be taken in a limiting sense, with the embodiment therein being defined by what is claimed instead.

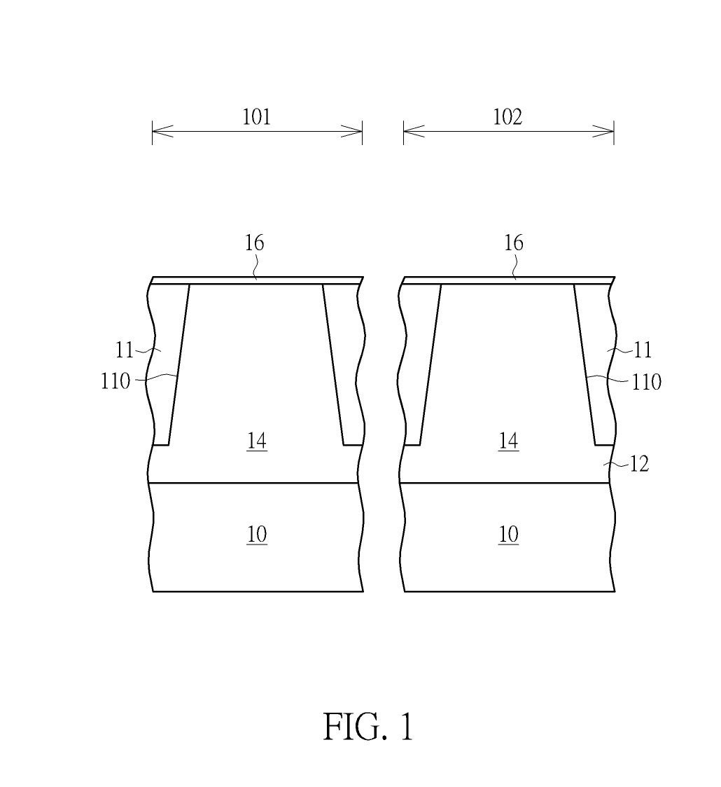

Please refer to FIGS. 1 to 6, which are cross-sectional view diagrams illustrating the method for fabricating a semiconductor memory according to an embodiment of the present invention. As shown in FIG. 1, a semiconductor substrate 10 such as a silicon substrate is provided, with the semiconductor substrate 10 being divided into a memory array region 101 and a peripheral circuit region, which can also be called a peripheral region 102. In accordance with the embodiment of the present invention, a recessed access device (RAD) and capacitors having a high density arrangement are formed in the memory array region 101, and a plurality of transistors is formed in the peripheral region 102.

Next, active areas are defined, This comprises forming an insulated or isolated trench 110 in a main surface of the semiconductor substrate 10 through lithographic and etching processes, followed by filling the insulated trench 110 with a material (for example, a spin on dielectric (SOD)), to form an insulated trench structure 11. Active areas 14 are thereby formed after a planarization process. An ion implantation process is then carried out to form an ion well 12, which can be P-type or N-type doped well.

An oxidizing process is carried out, forming an oxide layer 16 on the active areas 14, wherein the oxide layer 16 within the peripheral region 102 acts as a gate oxide layer of a transistor. The oxide layer 16 within the peripheral region 102 is allowed to have various thicknesses in accordance with different requirements of processes and component design. As an example, a low voltage device can have a lesser thickness, and a high voltage device can have a greater thickness.

Referring to the embodiment of the present invention illustrated in the accompanying figures, a surface treatment process can be further conducted after the forming of the oxide layer 16, by contacting surfaces of the oxide layer 16 with pure water through rinsing or spraying, for example. This contact transforms the dangling bonds on the surfaces of the oxide layer 16 and improves possible weak points. This surface treatment process means the semiconductor is able to avoid the re-growing of polysilicon along said weak points in the following processes, and further results in the breaking or rupture of the oxide layer 16. The surface treatment process can further comprise a spin dry step, which dries the surfaces of the oxide layer 16 after the water contact.

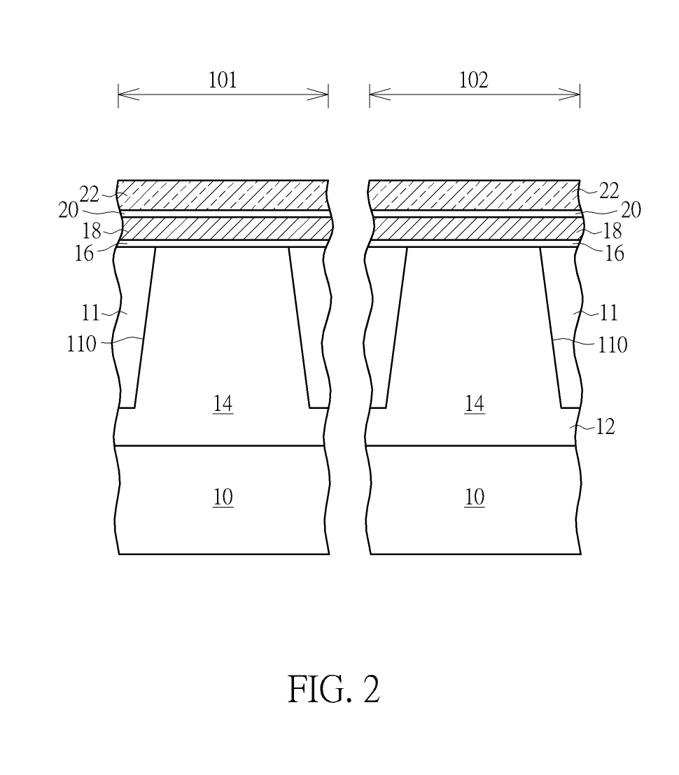

As illustrated in FIG. 2, a first polysilicon layer 18, a buffer layer 20, and a hard mask 22 are sequentially formed on the semiconductor substrate 10. According to the embodiment of the present invention, the first polysilicon layer 18 can comprise an undoped polysilicon layer, the buffer layer 20 can comprise silicon oxynitride, silicon oxide layer or aluminum oxide, and the hard mask 22 can comprise silicon nitride.

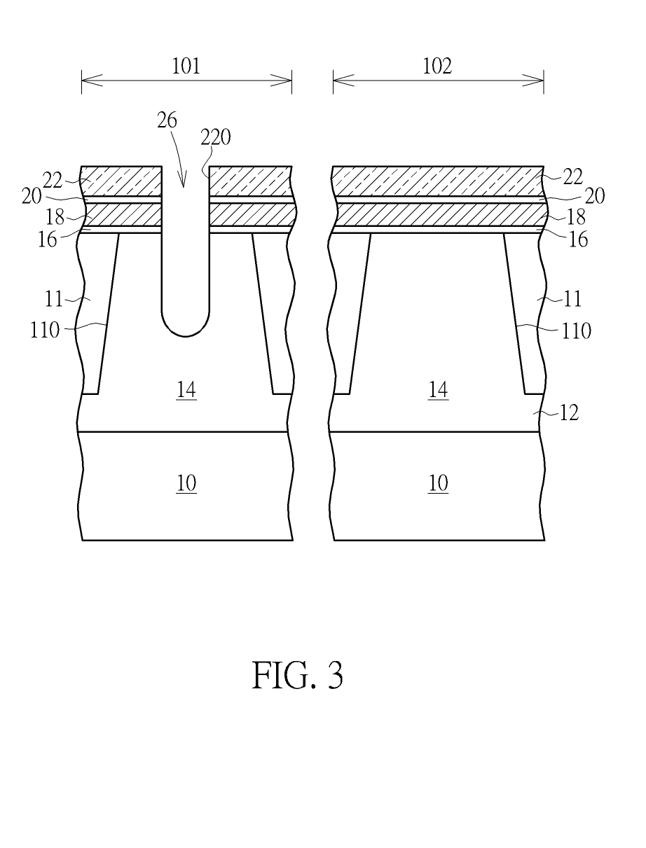

As illustrated in FIG. 3, an opening 220 of the recessed access devices in the hard mask 22 within the memory array region 101 is formed via lithographic and etching processes. A dry etching process can then be performed to etch the buffer layer 20, the first polysilicon layer 18, the oxide layer 16 and the semiconductor substrate 10 through the opening 220, under the sheltering of the hard mask 22, to form a RAD trench 26.

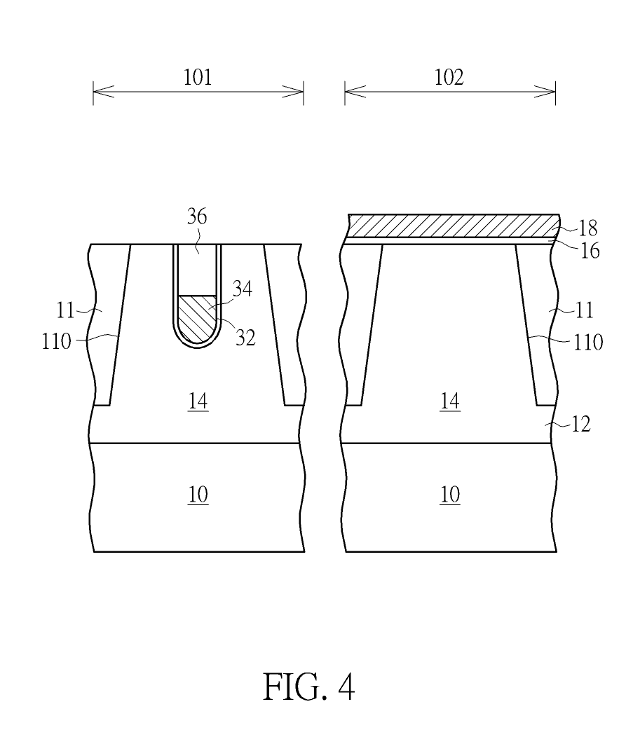

As illustrated in FIG. 4, fabricating said recessed access devices in the memory array region 101 comprises forming agate oxide layer 32 on surfaces of the RAD trench 26, followed by depositing metal into the RAD trench to form a metal gate 34, and then filling up the RAD trench 26 with a dielectric layer 36. By these steps, the fabricating of the recessed access devices in the memory array region 101 is achieved. The hard mask 22 and the buffer layer 20 can be removed subsequently. In accordance with the embodiment of the present invention, the first polysilicon layer 18 in the memory array region 101 can be optionally removed.

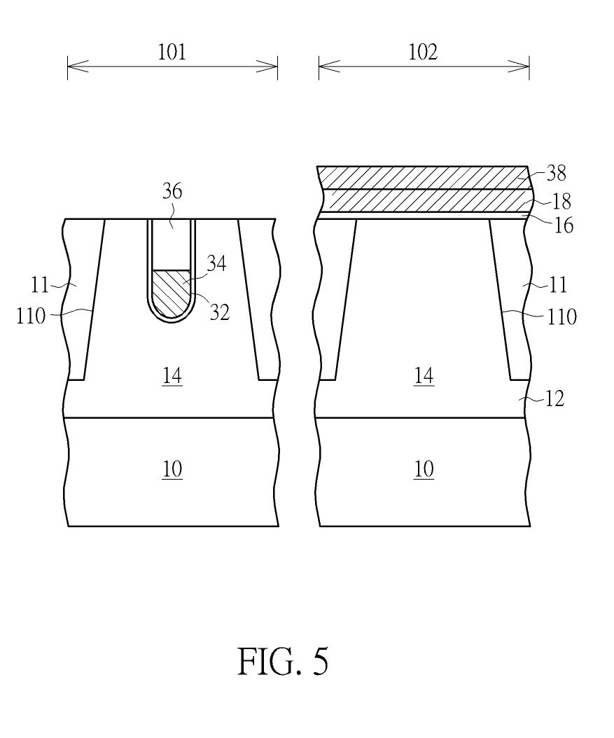

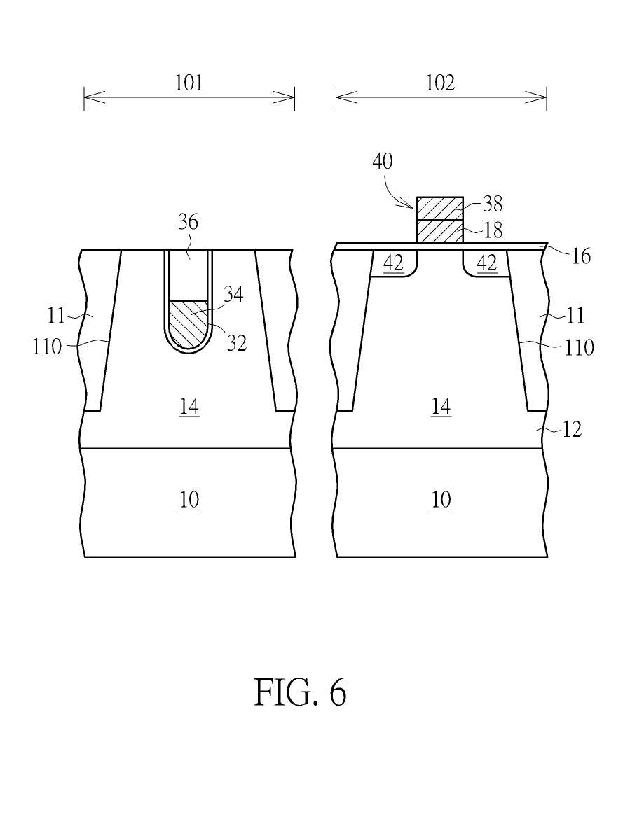

As illustrated in FIGS. 5 and 6, fabricating a planar type transistor in the peripheral region 102 comprises depositing a second polysilicon layer 38 on the first polysilicon 18 within the peripheral region 102, then patterning the first polysilicon layer 18 and the second polysilicon layers 38 by using lithographic and etching processes to form a gate structure 40, and finally forming a drain/source doping regions 42 in the semiconductor substrate 10 at two sides of the gate structure 40 through an ion implantation process.

In view of the embodiment of the present invention, a spacer (not shown in the drawings) can be formed at a lateral wall of the gate structure 40 before the forming of the drain/source doping regions 42.

In view of the embodiment of the present invention, a cleaning process can be performed before depositing the second polysilicon layer 38 to remove a native oxide layer formed on the surfaces of the first polysilicon layer 18.

In view of the embodiment of the present invention, the second polysilicon layer 38 comprises undoped polysilicon, and the polysilicon layer 38 can be further etched after depositing the second polysilicon layer 38 to remove a part of the second polysilicon layer 38 while saving another part of the second polysilicon layer 38 having a thickness of 300 angstroms (Å), thereby maintaining the smoothness of the memory array region.

In view of the embodiment of the present invention, the first polysilicon layer 18 and the second polysilicon layer 38 can be further doped with P-type or N-type dopants in the following steps.

In view of the embodiment of the present invention, an electric conducting layer (not shown in the drawings), such as tungsten, titanium nitride, titanium and tungsten silicide, can be further deposited after the depositing of the second polysilicon layer 38.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor memory, comprising:
providing a semiconductor substrate having a memory array region and a peripheral circuit region thereon;
forming active areas in the semiconductor substrate;
forming an oxide layer on the active areas, wherein the oxide layer acts as a gate oxide layer in the peripheral circuit region;
subjecting the oxide layer to a surface treatment;
depositing a first polysilicon layer, a buffer layer, and a hard mask on the oxide layer;
fabricating recessed access devices in the memory array region, comprising:
forming an opening in the hard mask within the memory array region by using lithographic and etching processes, performing a dry etching process to etch the buffer layer, the first polysilicon layer, the oxide layer, and the semiconductor substrate through the opening to thereby form a trench; forming a gate oxide layer on a surface of the trench; depositing metal into the trench; and filling the trench with a dielectric layer;
removing the hard mask and the buffer layer; and
fabricating transistors in the peripheral circuit region, comprising:
depositing a second polysilicon layer on the first polysilicon layer; and
patterning the first and second polysilicon layers into a gate structure.

2. The method for fabricating a semiconductor memory according to claim 1, wherein the surface treatment comprises contacting a surface of the oxide layer with pure water.

3. The method for fabricating a semiconductor memory according to claim 2, wherein the surface treatment further comprises a spin dry step.

4. The method for fabricating a semiconductor memory according to claim 1, wherein the first polysilicon comprises undoped polysilicon.

5. The method for fabricating a semiconductor memory according to claim 1, wherein the buffer layer comprises silicon oxynitride, silicon oxide layer or aluminum oxide.

6. The method for fabricating a semiconductor memory according to claim 1, wherein the hard mask comprises silicon nitride.

7. The method for fabricating a semiconductor memory according to claim 1, wherein the second polysilicon comprises undoped polysilicon.
